(19) United States
(12) Patent Application Publication
(10) Pub. No.: US 2011/0309375 A1
(43) Pub. Date: Dec. 22, 2011

(54) SEMICONDUCTOR DEVICE

(75) Inventor: Hajime KATO, Tokyo (JP)

(73) Assignee: MITSUBISHI ELECTRIC CORPORATION, Chiyoda-ku (JP)

(21) Appl. No.: 13/038,891

(22) Filed: Mar. 2, 2011

(30) Foreign Application Priority Data
Jun. 16, 2010 (JP) 2010-136940

(51) Int. Cl. H01L 29/12; H01L 23/34

(52) U.S. Cl. 257/77; 257/675; 257/E23.08; 257/E29.068

(57) ABSTRACT

A semiconductor device includes semiconductor elements mounted on a heat spreader, lead frames connected to the semiconductor elements, and a molding resin which holds them and forms a housing. Upper portions and side surfaces of the semiconductor elements are covered with an organic thin film which is formed between the semiconductor elements and the molding resin.

### BACKGROUND OF THE INVENTION

1. Field of the Invention

The present invention relates to a semiconductor device, and particularly to a structure of a semiconductor device for electric power which is supposed to be operated at a high temperature.

2. Description of the Background Art

As a package structure of a semiconductor device for electric power (power semiconductor device), often adopted are a structure (mold type) in which a power semiconductor element and a connecting member (a lead frame, a wire, or the like) are sealed with a molding resin, and a structure (casing type) in which a power semiconductor element and a connecting member are housed in a resin casing filled with a resin (for example, Japanese Patent Application Laid-Open No. 9-213878 (1997); Japanese Patent Application Laid-Open No. 2004-165281; and Japanese Patent Application Laid-Open No. 2002-324816).

Also known is a technique in which a coating of polyimide, parylene (paraxylene), or the like, is applied to a surface of a semiconductor element (for example, Japanese Patent Application Laid-Open No. 59-76451 (1984); Japanese Patent Application Laid-Open No. 6-216183 (1994); Japanese Patent Application Laid-Open No. 9-246307 (1997); Japanese Patent Application Laid-Open No. 61-111569 (1986); and Japanese Patent Application Laid-Open No. 2008-141052).

Generally, it is desirable that a resin for sealing a semiconductor element and a connecting member is excellent in characteristics such as insulating properties, a withstand voltage, heat dissipation properties, heat resistance, moisture resistance, thermal stress (the amount of stress caused by heat), mechanical properties (mechanical strength), adhesion properties, flowability (difficulty in generating air bubbles), and the like. However, some of these characteristics are incompatible with one another, and therefore, actually, a type and properties of an adopted resin are adjusted in accordance with specifications of a product.

For example, in an automobile, since there is a demand to reduce the size of an engine compartment in order to increase the interior space of the automobile, a power semiconductor device installed in the engine compartment is required to have a small size, a high output, and a high efficiency (low loss). On the other hand, downsizing of the engine compartment causes a problem of exhaust of heat of the power semiconductor device. Therefore, an in-car power semiconductor device is also required to have a still higher heat resistance.

Accordingly, expected is utilization of a semiconductor element, such as a silicon carbide (SiC) semiconductor element, capable of a high-temperature operation. For this purpose, it is necessary to increase a heat resistance (in a case of an epoxy resin which is a typical molding resin, a glass-transition temperature is approximately 180° C.) of a sealing resin. However, in a mold-type semiconductor device, increasing a heat resistance of a molding resin causes a problem of a deterioration in a moisture resistance, a deterioration in a mold formability, and the like. Additionally, in a case where a casing-type semiconductor device is used at a high temperature, a member (such as a wire) within a resin casing can be broken due to a stress arising in a resin which fills a resin casing. These problems hinder an improvement in a heat resistance of a semiconductor device.

### SUMMARY OF THE INVENTION

An object of the present invention is to provide a semiconductor device capable of improving a heat resistance while suppressing a deterioration in a moisture resistance.

A semiconductor device according to the present invention includes: a semiconductor element mounted on a heat spreader; a lead frame electrically connected to the semiconductor element; a molding resin which holds the semiconductor element, the heat spreader, and the lead frame, and forms a housing; and an organic thin film interposed between the semiconductor element and the molding resin. An upper portion and a side surface of the semiconductor element are covered with the organic thin film.

Generally, when a heat resistance of a molding resin is increased, a moisture resistance thereof tends to be reduced. In the semiconductor device according to the present invention, the organic thin film having an excellent moisture resistance is formed between the semiconductor element and the molding resin, and the molding resin is not required to have such a high moisture resistance. Thus, a molding resin having a high heat resistance can be used. Additionally, since the upper portion and the side surface of the semiconductor element are covered with the organic thin film, heat generated in the semiconductor element is efficiently dissipated to the heat spreader provided at the lower side. Therefore, an improvement in the heat resistance of the semiconductor device can be obtained while ensuring the moisture resistance thereof.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross-sectional view showing a configuration of a semiconductor device according to a preferred embodiment 1;

FIG. 2 is a diagram showing a method for forming an organic thin film of the semiconductor device according to the present invention;

FIG. 3 is a cross-sectional view showing a configuration of a semiconductor device according to a preferred embodiment 2;

FIG. 4 is a cross-sectional view showing a configuration of a semiconductor device according to a preferred embodiment 3; and

FIG. 5 is a cross-sectional view showing a configuration of a semiconductor device according to a preferred embodiment 4.

### DESCRIPTION OF THE PREFERRED EMBODIMENTS

### Preferred Embodiment 1

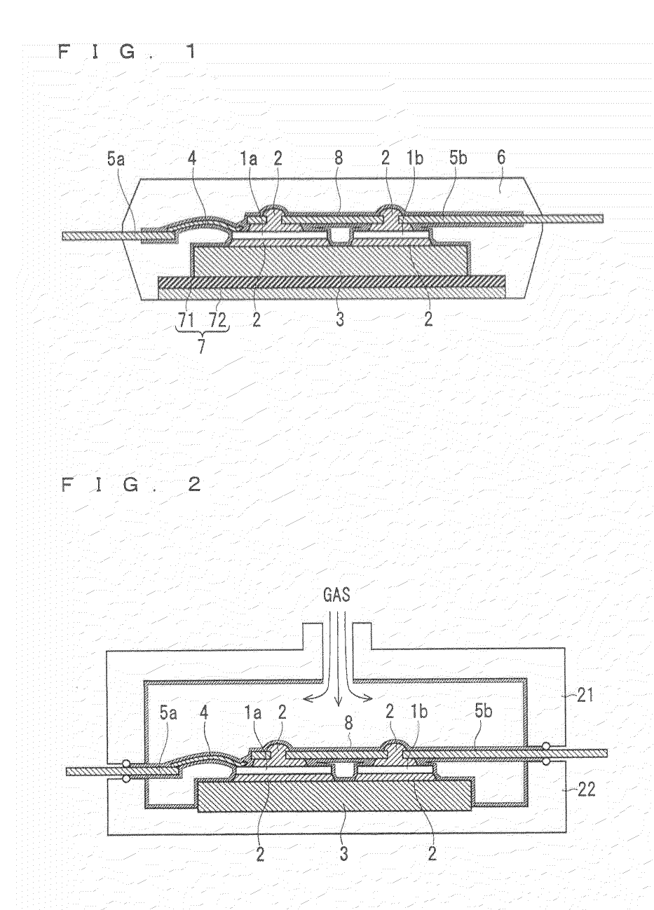

FIG. 1 is a cross-sectional view showing a configuration of a semiconductor device according to a preferred embodiment 1. As shown in FIG. 1, the semiconductor device is a mold-type module in which semiconductor elements 1a, 1b which are power semiconductor elements, a heat spreader 3 having the semiconductor elements 1a, 1b mounted thereon, and lead frames 5a, 5b which are electrically connected to the semiconductor elements 1a, 1b are held in a molding resin 6 serving as a housing.

In FIG. 1, two semiconductor elements 1a, 1b and two lead frames 5a, 5b are shown. The lead frame 5a is connected to the semiconductor element 1a through a wire 4 and the lead frame 5b is bonded to both of the semiconductor elements 1a, 1b by using a solder 2. The heat spreader 3 is formed of, for example, a metal having a high thermal conductivity. The semiconductor elements 1a, 1b are bonded to an upper surface of the heat spreader 3 by using the solder 2. A lower surface of the heat spreader 3 is exposed from the molding resin 6, and an insulating sheet 7 including an insulating resin layer 71 and a metal layer 72 having a high thermal conductivity is attached thereto.

A organic thin film 8 is formed between the molding resin 6 and the respective members (the semiconductor elements a, 1b, the solder 2, the heat spreader 3, the wire 4, and the lead frames 5a, 5b) held by the molding resin 6. Upper portions and side surfaces of the semiconductor elements 1a, 1b are completely covered with the organic thin film 8. On the other hand, no organic thin film 8 is formed at lower portions (at the heat spreader 3 side) of the semiconductor elements 1a, 1b.

In this preferred embodiment, a paraxylene-based polymer is used as the organic thin film 8, and a typical epoxy resin is used as the molding resin 6. The paraxylene-based polymer (parylene) has a high heat resistance of 250° C. to 350° C., and additionally has high thermal insulating properties because its thermal conductivity is equal to or less than 50% of an epoxy resin (having a representative value of 0.2 W/m/k). Moreover, in a polymer state, the paraxylene-based polymer has a lot of benzene rings and a cross-linked structure, and therefore is excellent in moisture resistance. On the other hand, in the epoxy resin, when a heat resistance and a mechanical strength are increased, a moisture resistance tends to be reduced.

In the structure shown in FIG. 1, surfaces of the semiconductor elements 1a, 1b, the solder 2, the heat spreader 3, the wire 4, and the lead frames 5a, 5b are covered with the organic thin film 8 having an excellent moisture resistance, and therefore the molding resin 6 is not required to have such a high moisture resistance. Thus, it is possible that an epoxy resin whose heat resistance and mechanical strength are increased (whose moisture resistance is low) is adopted as the molding resin 6.

Furthermore, the organic thin film 8 having high thermal insulating properties is interposed between the molding resin 6 and the upper portions and the side portions of the semiconductor elements 1a, 1b. This can suppress transfer of heat generated in the semiconductor elements 1a, 1b to the molding resin 6, and the heat can be efficiently dissipated to the heat spreader 3. This can contribute to an improvement in the heat resistance of the semiconductor device as a whole.

In this manner, according to the present invention, the heat resistance of the semiconductor device can be improved while ensuring the moisture resistance thereof. Thus, the upper limit of an ambient temperature at which the semiconductor device is usable can be set high, to realize a semiconductor device which can provide a high reliability even in a high-temperature environment (for example, 180° C. or higher). It is particularly effective when silicon carbide (SiC) semiconductor elements capable of a high-temperature operation are used as the semiconductor elements 1a, 1b.

In a case where each of the semiconductor elements 1a, 1b is a power transistor, an emitter electrode is arranged on an upper surface (active surface) thereof and a collector electrode is arranged on a lower surface thereof, and the highest voltage is applied to between them. The organic thin film 8 of the paraxylene-based polymer is also excellent in insulating properties. By forming the organic thin film 8 uniformly on the side surfaces of the semiconductor elements 1a, 1b, an effect of improved insulation between the emitter electrode and the collector electrode is also obtained.

FIG. 2 is a diagram for explaining a method for forming the organic thin film 8. The semiconductor elements 1a, 1b, the heat spreader 3, and the lead frames 5a, 5b are bonded by using the solder 2 and the wire 4, and subsequently they are placed in a container made up of an upper jig 21 and a lower jig 22 at a normal temperature. Then, a gasified paraxylene-based monomer is poured into the container.

When the gas of the paraxylene-based monomer comes into contact with a normal-temperature material, a polymerization of the paraxylene-based monomer progresses on a surface thereof, so that the paraxylene-based polymer is uniformly formed. As a result, the organic thin film 8 of the paraxylene-based polymer is uniformly formed on surfaces of the semiconductor elements 1a, 1b, the solder 2, the heat spreader 3, the wire 4, and the lead frames 5a, 5b within the container.

An appropriate thickness of the organic thin film 8 thus formed is 5 to 10 μm This is because a large thickness allows an increase in the moisture resistance and the withstand voltage but an excessively large thickness may cause an increase in a stress caused by a difference in the expansion coefficient between the organic thin film 8 and the respective members.

Here, in this preferred embodiment, the insulating sheet 7 is attached to the lower surface of the heat spreader 3 in a subsequent step. Therefore, the lower surface of the heat spreader 3 is brought into tight contact with the lower jig 22 so that no organic thin film 8 is formed thereon.

When the method for forming the organic thin film 8 using a gas of an organic material in this manner is adopted, the organic thin film 8 can be uniformly formed on a surface of a material even if the material has a complicated shape. Accordingly, the organic thin film 8 can be uniformly formed between the upper surfaces of the semiconductor elements 1a, 1b and the lead frame 5b, and on the surface of the thin wire 4. Additionally, the thickness of the growth (deposition) of the organic thin film 8 can be controlled in the order of micron, and characteristics having a trade-off relationship with one another, such as a thermal stress and insulating properties resulting from the thickness of the organic thin film 8, can be easily adjusted with a high accuracy.

### Preferred Embodiment 2

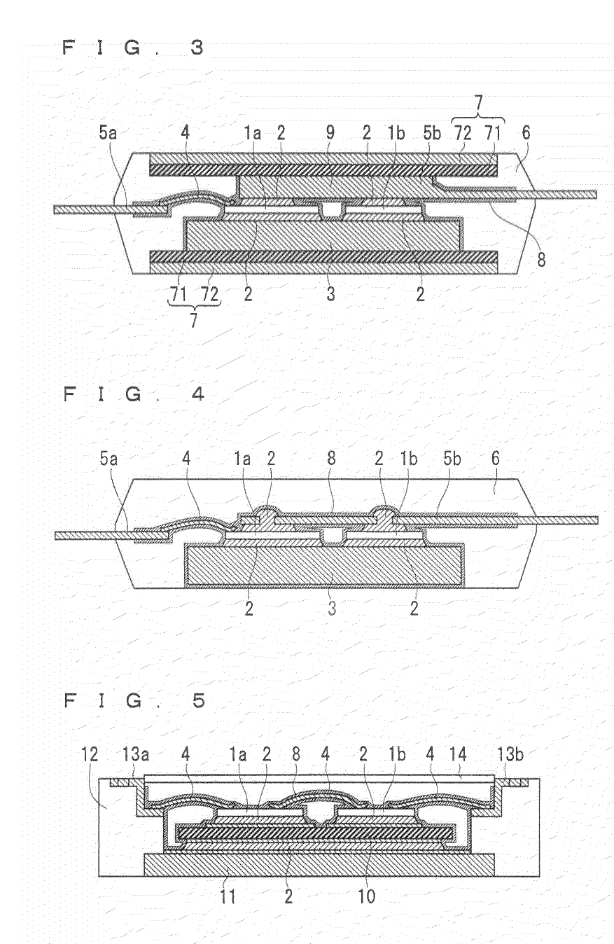

FIG. 3 is a cross-sectional view showing a configuration of a semiconductor device according to a preferred embodiment 2. The configuration of this semiconductor device is the same as the configuration shown in FIG. 1, except that a heat spreader is also provided on upper surfaces of the semiconductor elements 1a, 1b. Here, the lead frame 5b is partially thickened so as to function as a heat spreader 9. Thus, the semiconductor elements 1a, 1b are interposed between the upper heat spreader 9 and the lower heat spreader 3. An upper surface of the heat spreader 9, which is a part of the lead frame 5b, is exposed from the molding resin 6, and the insulating sheet 7 is attached thereto.

In this preferred embodiment, too, the organic thin film 8 is formed between the molding resin 6 and the respective members (the semiconductor elements 1a, 1b, the solder 2, the heat spreader 3, the wire 4, and the lead frames 5a, 5b) held by the molding resin 6. Similarly to in the preferred embodiment 1, the side surfaces of the semiconductor elements 1a, 1b are completely covered with the organic thin film 8. The heat spreader 9 is arranged on the upper portions of the semiconductor elements 1a, 1b, and therefore the upper portions of the semiconductor elements 1a, 1b are, except a part thereof (a portion thereof confronting the molding resin 6), not covered with the organic thin film 8. Similarly to in the preferred embodiment 1, no organic thin film 8 is formed at the lower portions (at the heat spreader 3 side) of the semiconductor elements 1a, 1b.

In this preferred embodiment, higher heat dissipation properties can be obtained because the heat spreaders 9 and 3 are provided at the upper surface side and the lower surface side of the semiconductor device, respectively. Additionally, the organic thin film 8 having high thermal insulating properties is interposed between the molding resin 6 and the side portions of the semiconductor elements 1a, 1b. This can suppress transfer of heat generated in the semiconductor elements 1a, 1b to the molding resin 6, and the heat can be efficiently dissipated to the heat spreaders 3, 9.

Here, each of the intervals between the semiconductor elements 1a, 1b and the heat spreader 3 and between the semiconductor elements 1a, 1b and the heat spreader 9 (lead frame 5b) (in other words, the thickness of the solders 2 existing therebetween) is approximately several hundred μm. Particularly in a configuration in which the heat spreaders 9, 3 are provided at the upper and lower portions of the semiconductor elements 1a, 1b as shown in FIG. 3, it is more advantageous that the solder 2 has a small thickness, in terms of cooling capability. However, a small thickness causes a space between the lead frame 5b and the heat spreader 3 (between the emitter electrode and the collector electrode) to be narrowed, so that a void is likely to occur at that portion of the molding resin 6. This is disadvantageous in terms of the insulating properties.

Similarly to the preferred embodiment 1, when the organic thin film 8 is formed by the method using a gas of an organic material, the organic thin film 8 having high insulating properties can be uniformly formed in such a narrow space. Therefore, even if a void occurs, a deterioration in the insulation between the lead frame 5b and the heat spreader 3 can be suppressed. That is, by forming the organic thin film 8 by the method using a gas of an organic material, the thickness of the solder 2 can be reduced to enhance heat dissipation performance while preventing a deterioration in the insulating properties of the semiconductor device.

### Preferred Embodiment 3

FIG. 4 is a cross-sectional view showing a configuration of a semiconductor device according to a preferred embodiment 3. In this preferred embodiment, the organic thin film 8 is also formed on the lower surface of the heat spreader 3 exposed from the molding resin 6. Since the organic thin film 8 has excellent insulating properties, it is no longer necessary to attach the insulating sheet 7 to the lower surface of the heat spreader 3. Thus, the manufacturing costs can be reduced.

In order to form the organic thin film 8 on the lower surface of the heat spreader 3, a gas of an organic material may be poured into the container with the heat spreader 3 being lifted up from the lower jig 22, in the method for forming the organic thin film 8 as described with reference to FIG. 2.

This preferred embodiment is applicable to the preferred embodiment 2, too. In the configuration shown in FIG. 3, the organic thin film 8 may be formed on the lower surface of the heat spreader 3 and the upper surface of the heat spreader 9. In this case, the insulating sheet 7 of the heat spreader 9 may be omitted, too.

### Preferred Embodiment 4

In the preferred embodiments 1 to 3, a mold-type semiconductor device is shown as an example. However, the present invention is also applicable to a casing-type semiconductor device. Here, an exemplary case where the present invention is applied to a casing-type semiconductor device will be shown.

FIG. 5 is a cross-sectional view showing a configuration of a semiconductor device according to a preferred embodiment 4. The semiconductor elements 1a, 1b are fixed onto a metallized insulating substrate 10 (supporting substrate) through the solder 2. The semiconductor elements 1a, 1b and the metallized insulating substrate 10 are housed in a resin casing 12. A heat dissipation plate 11 is provided at a bottom portion of the resin casing 12. The metallized insulating substrate 10 is fixed on the heat dissipation plate 11 by using the solder 2.

The resin casing 12 has terminal portions 13a, 13b. In the example shown in FIG. 5, the semiconductor element 1a is connected to the terminal portion 13a through the wire 4, and the semiconductor element 1b is connected to the terminal portion 13b through the wire 4. The semiconductor elements 1a, 1b are also connected to each other through the wire 4.

In this preferred embodiment, the metallized insulating substrate 10 having the semiconductor elements 1a, 1b mounted thereon is fixed onto the heat dissipation plate 11 within the resin casing 12, and wiring is performed by using the wires 4. Subsequently, the organic thin film 8 is formed within the resin casing 12. A method for forming the organic thin film 8 may be the method (FIG. 2) using a gas of an organic material similarly to in the preferred embodiment 1.

In this preferred embodiment, the organic thin film 8 is formed on surfaces of the respective members (the semiconductor elements 1a, 1b, the solder 2, the wire 4, and the metallized insulating substrate 10) housed in the resin casing 12, and on a surface of an internal surface (including the terminal portion 13b and the heat dissipation plate 11) of the resin casing 12. Here, an appropriate thickness of the organic thin film 8 is approximately 5 to 10 μm. Focusing on parts of the organic thin film 8 around the semiconductor elements 1a, 1b, the upper portions and the side surfaces of the semiconductor elements 1a, 1b are completely covered with the organic thin film 8. On the other hand, no organic thin film 8 is formed at the lower portions (at the metallized insulating substrate 10 side) of the semiconductor elements 1a, 1b.

In order to improve the moisture resistance and the withstand voltage, it may be acceptable that, after the organic thin film 8 is formed, a resin such as a silicon gel fills the resin casing 12 in the same manner as conventional and the resin casing 12 is sealed with a cap 14. However, in this preferred embodiment, the organic thin film 8 having excellent heat resistance and excellent moisture resistance is formed on the surfaces of the respective members which are housed in the resin casing 12. Therefore, filling of the resin may be omitted (air is sealed within the resin casing 12).

In this preferred embodiment, since the organic thin film 8 which covers the surfaces of the respective members housed in the resin casing 12 is extremely thin (approximately 5 to 10 μm), an increase in the stress caused by a difference in the thermal expansion coefficient between the organic thin film 8 and the respective members is prevented.

Furthermore, the upper portions and the side portions of the semiconductor elements 1a, 1b are covered with the organic thin film 8 having high thermal insulating properties. This can suppress transfer of heat generated in the semiconductor elements 1a, 1b to the molding resin 6, and the heat can be efficiently dissipated to the heat spreader 3. This can contribute to an improvement in the heat resistance of the semiconductor device as a whole.

Although in a conventional casing-type semiconductor device, a resin such as a silicon gel normally fills the resin casing, it can be omitted in this preferred embodiment. Omission of filling of the resin obviously allows a reduction in the manufacturing costs, and moreover can avoid the problem that the member (such as the wire 4) in the resin casing 12 is damaged by a stress occurring in the resin when the semiconductor device is used at a high temperature. This can contribute to extension of the temperature cycle lifetime of the semiconductor device.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device comprising:
a semiconductor element mounted on a heat spreader;
a lead frame electrically connected to said semiconductor element;
a molding resin which holds said semiconductor element, said heat spreader, and said lead frame, and forms a housing; and
an organic thin film interposed between said semiconductor element and said molding resin,
wherein an upper portion and a side surface of said semiconductor element are covered with said organic thin film.

2. The semiconductor device according to claim 1, wherein
a lower surface of said heat spreader is exposed from said molding resin, and an insulating sheet is attached thereto.

3. The semiconductor device according to claim 1, wherein
a lower surface of said heat spreader is exposed from said molding resin,
said organic thin film also covers the lower surface of said heat spreader.

4. The semiconductor device according to claim 1, wherein
said semiconductor element is a silicon carbide semiconductor element.

5. A semiconductor device comprising:
a semiconductor element arranged between a first heat spreader at an upper side and a second heat spreader at a lower side;
a lead frame electrically connected to said semiconductor element;
a molding resin which holds said semiconductor element, said first and second heat spreaders, and said lead frame, and forms a housing; and
an organic thin film interposed between said semiconductor element and said molding resin,
wherein a side surface of said semiconductor element is covered with said organic thin film.

6. The semiconductor device according to claim 5, wherein
an upper surface of said first heat spreader and a lower surface of said second heat spreader are exposed from said molding resin, and insulating sheets are attached thereto.

7. The semiconductor device according to claim 5, wherein
an upper surface of said first heat spreader and a lower surface of said second heat spreader are exposed from said molding resin,
said organic thin film also covers the upper surface of said first heat spreader and the lower surface of said second heat spreader.

8. The semiconductor device according to claim 5, wherein
said semiconductor element is a silicon carbide semiconductor element.

9. A semiconductor device comprising:
a semiconductor element;
a supporting substrate having said semiconductor element mounted thereon;
a resin casing which has a terminal portion electrically connected to said semiconductor element through wiring and in which said semiconductor device and said supporting substrate are housed; and
an organic thin film formed on a surface of said semiconductor element,
wherein
said supporting substrate is placed on a heat dissipation plate provided at a bottom of said resin casing,
an upper portion and a side surface of said semiconductor element are covered with said organic thin film.

10. The semiconductor device according to claim 9, wherein
said resin casing is filled with no resin.

11. The semiconductor device according to claim 9, wherein
said semiconductor element is a silicon carbide semiconductor element.
